(19) United States
(12) Patent Application Publication
(10) Pub. No.: US 2026/0179881 A1
(43) Pub. Date: Jun. 25, 2026

(54) PLASMA PROCESSING APPARATUS AND PROGRAM

(71) Applicant: Tokyo Electron Limited, Tokyo (JP)

(72) Inventors: Toshihiro TSURUTA, Kurokawa-gun (JP); Yoshinori SUZUKI, Kurokawa-gun (JP)

(21) Appl. No.: 19/541,832

(22) Filed: Feb. 17, 2026

Related U.S. Application Data
(63) Continuation of application No. PCT/JP2024/029022, filed on Aug. 15, 2024.

(30) Foreign Application Priority Data
Sep. 1, 2023 (JP) 2023-142498
Jan. 5, 2024 (JP) 2024-000814

(51) Int. Cl. H01J 37/32

(52) U.S. Cl. CPC H01J 37/32192; H01J 37/321; H01J 37/32165; H01J 37/32174; H01J 37/32568

(57) ABSTRACT

A plasma processing apparatus includes a controller including a storage and a processor. The storage stores a first rule including a first change rule and a second change rule. The processor includes a first recipe obtainer, a second recipe obtainer, a transition recipe generator, a first recipe changer, a second recipe changer, and a transition recipe changer. The first recipe obtainer obtains a first recipe. The second recipe obtainer obtains a second recipe. The transition recipe generator generates a transition recipe from the first recipe and the second recipe. The first recipe changer changes the first recipe over time based on an operation time of a radio-frequency power supply. The second recipe changer changes the second recipe over time based on an operation time of the radio-frequency power supply. The transition recipe changer changes the transition recipe.

This application is a bypass continuation application of international application No. PCT/JP2024/029022 having an international filing date of August 15, 2024, and designating the United States, the international application being based upon and claiming the benefit of priority from Japanese Patent Application No. 2023-142498, filed on September 1, 2023, and Japanese Patent Application No. 2024-000814, filed on January 5, 2024, the entire contents of which are incorporated herein by reference.

### BACKGROUND

### Field of the Invention

Exemplary embodiments of the present disclosure relate to a plasma processing apparatus and a program.

### Description of Related Art

JP2021-39924 describes a plasma processing apparatus including a controller with a processor that controls components of the plasma processing apparatus based on recipe data, performing various processes.

### SUMMARY

A plasma processing apparatus according to one exemplary embodiment of the present disclosure includes a chamber, a gas supply, a radio-frequency power supply, and a controller. The gas supply supplies a processing gas into the chamber. The radio-frequency power supply generates radio-frequency power to generate a plasma from the processing gas supplied into the chamber. The controller controls the gas supply and the radio-frequency power supply. The controller includes a storage and a processor. The storage stores a first rule including a first change rule and a second change rule. The processor includes a first recipe obtainer, a second recipe obtainer, a transition recipe generator, a first recipe changer, a second recipe changer, and a transition recipe changer. The first recipe obtainer obtains a first recipe for first plasma processing. The first recipe includes a first set power level of the radio-frequency power and a first set flow rate of the processing gas. The second recipe obtainer obtains a second recipe for second plasma processing. The second recipe includes a second set power level of the radio-frequency power and a second set flow rate of the processing gas. The transition recipe generator generates a transition recipe for transition performed between the first plasma processing and the second plasma processing. The transition recipe includes a plurality of transition flow rates changeable from the first set flow rate to the second set flow rate based on the first change rule and a plurality of transition power levels changeable from the first set power level to the second set power level based on the second change rule. The first recipe changer changes the first recipe over time based on an operation time of the radio-frequency power supply and changes the first set power level and the first set flow rate over time. The second recipe changer changes the second recipe over time based on an operation time of the radio-frequency power supply and changes the second set power level and the second set flow rate over time. The transition recipe changer changes the transition recipe based on the changed first recipe and the changed second recipe. The changed transition recipe includes a plurality of changed transition flow rates changeable from the changed first set flow rate to the changed second set flow rate based on the first change rule and a plurality of changed transition power levels changeable from the changed first set power level to the changed second set power level based on the second change rule.

### BRIEF DESCRIPTION OF DRAWINGS

FIG. 1 is a system diagram of an example plasma processing system.

FIG. 2 is a diagram of an example rule creation apparatus.

FIG. 3 is a diagram of an example plasma processing apparatus.

FIG. 4 is a diagram of an example computer included in a controller.

FIG. 5 is a table showing an example set recipe.

FIG. 6 is a table showing example set recipes and an example transition recipe.

FIG. 7 is a graph showing example changes in a parameter value in the transition recipe.

FIG. 8 is a graph showing other example changes in the parameter value in a transition recipe.

FIG. 9 is a graph showing other example changes in the parameter value in transition recipes.

FIG. 10 is a table showing example changed set recipes and an example changed transition recipe.

FIG. 11 is a flowchart of an example plasma processing method.

FIG. 12 is a table showing another example set recipe.

FIG. 13 is a table showing other example set recipes and another example transition recipe.

FIG. 14 is a table showing other example changed set recipes and another example changed transition recipe.

FIG. 15 is a table showing a recipe in a reference example.

### DETAILED DESCRIPTION

One or more embodiments of the present disclosure will be described below.

A plasma processing apparatus according to one exemplary embodiment includes a chamber, a gas supply, a radio-frequency power supply, and a controller. The gas supply supplies a processing gas into the chamber. The radio-frequency power supply generates radio-frequency power to generate a plasma from the processing gas supplied into the chamber. The controller controls the gas supply and the radio-frequency power supply. The controller includes a storage and a processor. The storage stores a first rule including a first change rule and a second change rule. The processor includes a first recipe obtainer, a second recipe obtainer, a transition recipe generator, a first recipe changer, a second recipe changer, and a transition recipe changer. The first recipe obtainer obtains a first recipe for first plasma processing. The first recipe includes a first set power level of the radio-frequency power and a first set flow rate of the processing gas. The second recipe obtainer obtains a second recipe for second plasma processing. The second recipe includes a second set power level of the radio-frequency power and a second set flow rate of the processing gas. The transition recipe generator generates a transition recipe for transition performed between the first plasma processing and the second plasma processing. The transition recipe includes a plurality of transition flow rates changeable from the first set flow rate to the second set flow rate based on the first change rule and a plurality of transition power levels changeable from the first set power level to the second set power level based on the second change rule. The first recipe changer changes the first recipe over time based on an operation time of the radio-frequency power supply and changes the first set power level and the first set flow rate over time. The second recipe changer changes the second recipe over time based on an operation time of the radio-frequency power supply and changes the second set power level and the second set flow rate over time. The transition recipe changer changes the transition recipe based on the changed first recipe and the changed second recipe. The changed transition recipe includes a plurality of changed transition flow rates changeable from the changed first set flow rate to the changed second set flow rate based on the first change rule and a plurality of changed transition power levels changeable from the changed first set power level to the changed second set power level based on the second change rule.

In one exemplary embodiment, the controller further includes a rule obtainer that obtains the first rule from an external device through a network and causes the storage to store the first rule.

In one exemplary embodiment, the first recipe obtainer obtains the first recipe from the external device through the network and causes the storage to store the first recipe. The second recipe obtainer obtains the second recipe from the external device through the network and causes the storage to store the second recipe.

In one exemplary embodiment, the storage further stores a second rule. The first recipe changer changes the first set power level and the first set flow rate over time based on the second rule. The second recipe changer changes the second set power level and the second set flow rate over time based on the second rule.

In one exemplary embodiment, the controller further includes a rule obtainer that obtains the first rule and the second rule from an external device through a network and causes the storage to store the first rule and the second rule.

A program according to one exemplary embodiment of the present disclosure is a program for controlling a plasma processing apparatus. The plasma processing apparatus includes a chamber, a gas supply that supplies a processing gas into the chamber, a radio-frequency power supply that generates radio-frequency power to generate a plasma from the processing gas supplied into the chamber, and a controller that controls the gas supply and the radio-frequency power supply. The controller includes a storage and a processor. The program causes the processor in the controller to perform processes including (a) causing the storage to store a first rule including a first change rule and a second change rule, (b) obtaining, for first plasma processing, a first recipe including a first set power level of the radio-frequency power and a first set flow rate of the processing gas, (c) obtaining, for second plasma processing, a second recipe including a second set power level of the radio-frequency power and a second set flow rate of the processing gas, (d) generating, for transition performed between the first plasma processing and the second plasma processing, a transition recipe including a plurality of transition flow rates changeable from the first set flow rate to the second set flow rate based on the first change rule and a plurality of transition power levels changeable from the first set power level to the second set power level based on the second change rule, (e) changing the first recipe over time based on an operation time of the radio-frequency power supply and changing the first set power level and the first set flow rate over time, (f) changing the second recipe over time based on an operation time of the radio-frequency power supply and changing the second set power level and the second set flow rate over time, and (g) changing the transition recipe based on the changed first recipe and the changed second recipe. The changed transition recipe includes a plurality of changed transition flow rates changeable from the changed first set flow rate to the changed second set flow rate based on the first change rule, and a plurality of changed transition power levels changeable from the changed first set power level to the changed second set power level based on the second change rule.

In one exemplary embodiment, (a) includes obtaining the first rule from an external device through a network and causing the storage to store the first rule.

In one exemplary embodiment, (b) includes obtaining the first recipe from the external device through the network and causing the storage to store the first recipe, and (c) includes obtaining the second recipe from the external device through the network and causing the storage to store the second recipe.

In one exemplary embodiment, (a) includes causing the storage to store a second rule, (e) includes changing the first set power level and the first set flow rate over time based on the second rule, and (f) includes changing the second set power level and the second set flow rate over time based on the second rule.

In one exemplary embodiment, (a) includes obtaining the first rule and the second rule from an external device through a network and causing the storage to store the first rule and the second rule.

A plasma processing apparatus according to one exemplary embodiment includes a chamber, a radio-frequency power supply, and a controller. The radio-frequency power supply generates radio-frequency power to generate a plasma in the chamber. The controller includes a storage and a processor. The storage stores a first rule. The processor includes a first recipe obtainer, a second recipe obtainer, a transition recipe generator, a first recipe changer, a second recipe changer, and a transition recipe changer. The first recipe obtainer obtains a first recipe for first plasma processing. The first recipe includes a first set level of a set parameter. The second recipe obtainer obtains a second recipe for second plasma processing. The second recipe includes a second set level of the set parameter. The transition recipe generator generates a transition recipe for transition performed between the first plasma processing and the second plasma processing. The transition recipe includes a plurality of transition set levels changeable from the first set level to the second set level based on the first rule. The first recipe changer changes the first recipe over time based on an operation time of the radio-frequency power supply and changes the first set level over time. The second recipe changer changes the second recipe over time based on an operation time of the radio-frequency power supply and changes the second set level over time. The transition recipe changer changes the transition recipe based on the changed first recipe and the changed second recipe. The changed transition recipe includes a plurality of changed transition set levels changeable from the changed first set level to the changed second set level based on the first rule.

In one exemplary embodiment, the controller further includes a rule obtainer that obtains the first rule from an external device through a network and causes the storage to store the first rule.

In one exemplary embodiment, the first recipe obtainer obtains the first recipe from the external device through the network and causes the storage to store the first recipe.

In one exemplary embodiment, the storage further stores a second rule, the first recipe changer changes the first set level over time based on the second rule, and the second recipe changer changes the second set level over time based on the second rule.

In one exemplary embodiment, the controller further includes a rule obtainer that obtains the first rule and the second rule from an external device through a network and causes the storage to store the first rule and the second rule.

In one exemplary embodiment, the set parameter is at least one of a power level of the radio-frequency power, a flow rate of a processing gas supplied into the chamber, or a pressure in the chamber.

One or more embodiments of the present disclosure will now be described with reference to the drawings. In the drawings, like reference numerals denote the same or like components. Such components will not be described repeatedly. Unless otherwise specified, the positional relationships shown in the drawings are used to describe the vertical, lateral, and other positions. The drawings are not drawn to scale relative to the actual ratio of each component, and the actual ratio is not limited to the ratio in the drawings.

A plasma processing apparatus includes hardware and software. The software includes parts that are adjustable by the user of the plasma processing apparatus and parts that are adjustable by the apparatus manufacturer and non-adjustable by the user. Complicated processing and shorter apparatus delivery time in recent years may cause fine processing adjustments after the hardware is complete, causing software change after the hardware is shipped.

The parts of the software that are non-adjustable by the user may include, for example, parts that are based on the hardware. Such software includes rules for creating a recipe to be automatically inserted between recipes created by the user. These rules are created and incorporated into the plasma processing apparatus by the manufacturer of the plasma processing apparatus. However, the rules may be corrected during operation of the plasma processing apparatus. The recipes or the rules may be corrected when, for example, the hardware configuration of the plasma processing apparatus is changed or when worn components change the state of the chamber.

### Structure of Plasma Processing System 1

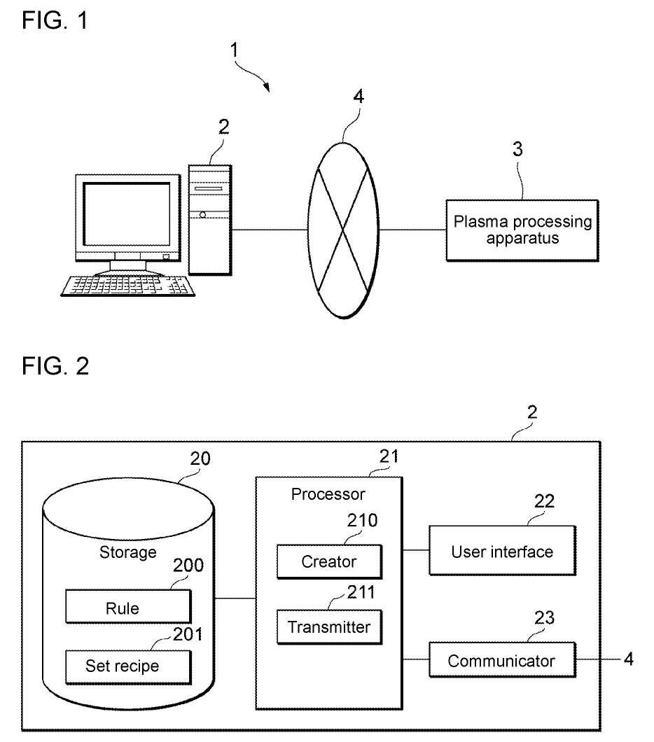

FIG. 1 is a system diagram of an example of a plasma processing system 1. The plasma processing system 1 includes a creation apparatus 2 and a plasma processing apparatus 3. The creation apparatus 2 and the plasma processing apparatus 3 communicate to transmit and receive data to and from each other through a network 4. The creation apparatus 2 is an example of a rule creation apparatus.

The creation apparatus 2 creates set recipes in response to a user operation, and transmits the created set recipes to the plasma processing apparatus 3 through the network 4. The creation apparatus 2 also creates rules in response to a user operation, and transmits the created rules to the plasma processing apparatus 3 through the network 4. The rules include a first rule and a second rule. The first rule is used to generate a transition recipe for transition processes performed between first plasma processing and second plasma processing. The second rule is used to change the values of set parameters for the first plasma processing and the values of the set parameters for the second plasma processing based on an operation time of a radio-frequency (RF) power supply.

The plasma processing apparatus 3 obtains the set recipes and the rules from the creation apparatus 2 through the network 4. The plasma processing apparatus 3 also generates a transition recipe based on the first rule of the obtained rules. The plasma processing apparatus 3 also changes the set recipe based on the second rule of the obtained rules to generate a changed set recipe. The plasma processing apparatus 3 also changes the transition recipe based on the first rule and the second rule of the obtained rules to generate a changed transition recipe. The plasma processing apparatus 3 performs processing such as film deposition or etching on a substrate W based on the set recipe, the transition recipe, the changed set recipe, and the changed transition recipe.

### Structure of Creation Apparatus 2

FIG. 2 is a diagram of an example of the creation apparatus 2. The creation apparatus 2 includes a storage 20, a processor 21, a user interface 22, and a communicator 23.

The storage 20 stores rules 200 and set recipes 201. The rules 200 include the first rule and the second rule. The set recipes 201 include a first recipe including the values of the set parameters for the first plasma processing and a second recipe including the values of the set parameters for the second plasma processing.

The processor 21 includes a creator 210 and a transmitter 211. The creator 210 creates the first rule and the second rule in response to a user operation through the user interface 22, and stores the rules 200 including the created first rule and the created second rule into the storage 20. The creator 210 also creates the set recipes 201 in response to a user operation through the user interface 22, and stores the created set recipes 201 into the storage 20. The creator 210 is an example of a rule creator.

The communicator 23 communicates with the plasma processing apparatus 3 through the network 4. The transmitter 211 transmits the rules 200 and the set recipes 201 stored in the storage 20 to the plasma processing apparatus 3 through the communicator 23 and the network 4.

### Structure of Plasma Processing Apparatus 3

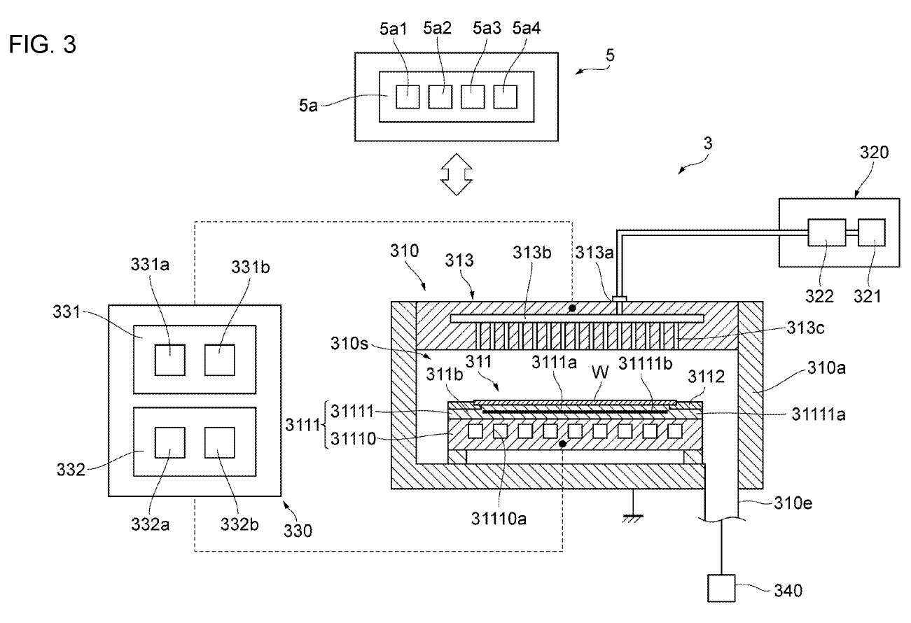

FIG. 3 is a diagram of an example of the plasma processing apparatus 3. The plasma processing apparatus 3 is an example of a substrate processing apparatus. FIG. 3 shows a capacitively coupled plasma processing apparatus 3 as an example.

The capacitively coupled plasma processing apparatus 3 includes a plasma processing chamber 310, a gas supply 320, a power supply 330, and an exhaust system 340. The plasma processing apparatus 3 includes a substrate support 311 and a gas guide unit. The gas guide unit allows at least one processing gas to be introduced into the plasma processing chamber 310. The gas guide unit includes a showerhead 313. The substrate support 311 is located in the plasma processing chamber 310. The showerhead 313 is located above the substrate support 311. In one embodiment, the showerhead 313 defines at least a part of the ceiling of the plasma processing chamber 310. The plasma processing chamber 310 has a plasma processing space 310s defined by the showerhead 313, a sidewall 310a of the plasma processing chamber 310, and the substrate support 311. The plasma processing chamber 310 has at least one gas inlet for supplying at least one processing gas into the plasma processing space 310s and at least one gas outlet for exhausting the gas from the plasma processing space. The plasma processing chamber 310 is grounded. The showerhead 313 and the substrate support 311 are electrically insulated from the housing of the plasma processing chamber 310.

The substrate support 311 includes a body 3111 and a ring assembly 3112. The body 3111 includes a central portion 3111a for supporting a substrate W and an annular portion 3111b for supporting the ring assembly 3112. A wafer is an example of the substrate W. The annular portion 3111b of the body 3111 surrounds the central portion 3111a of the body 3111 as viewed in plan. The substrate W is placeable on the central portion 3111a of the body 3111. The ring assembly 3112 is located on the annular portion 311b of the body 3111 to surround the substrate W on the central portion 3111a of the body 3111. Thus, the central portion 3111a is also referred to as a substrate support surface for supporting the substrate W. The annular portion 3111b is also referred to as a ring support surface for supporting the ring assembly 3112.

In one embodiment, the body 3111 includes a base 31110 and an electrostatic chuck (ESC) 31111. The base 31110 includes a conductive member. The conductive member in the base 31110 may function as a lower electrode. The ESC 31111 is located on the base 31110. The ESC 31111 includes a ceramic member 31111a and an electrostatic electrode 31111b located inside the ceramic member 31111a. The ceramic member 31111a includes the central portion 3111a. In one embodiment, the ceramic member 31111a also includes the annular portion 3111b. The annular portion 3111b may be included in another member surrounding the ESC 31111, such as an annular ESC or an annular insulating member. In this case, the ring assembly 3112 may be located on the annular ESC or the annular insulating member, or may be located on both the ESC 31111 and the annular insulating member. At least one RF/direct-current (DC) electrode coupled to an RF power supply 331 or a DC power supply 332, or both (described later) may be located inside the ceramic member 31111a. In this case, the RF/DC electrode functions as a lower electrode. When a bias RF signal or a DC signal, or both (described later) are provided to at least one RF/DC electrode, the RF/DC electrode is also referred to as a bias electrode. The conductive member in the base 31110 and at least one RF/DC electrode may function as multiple lower electrodes. The electrostatic electrode 31111b may also function as a lower electrode. The substrate support 311 thus includes at least one lower electrode.

The ring assembly 3112 includes one or more annular members. In one embodiment, the one or more annular members include one or more edge rings and at least one cover ring. The edge rings are formed from a conductive material or an insulating material. The cover ring is formed from an insulating material.

The substrate support 311 may include a temperature controller that adjusts the temperature of at least one of the ESC 31111, the ring assembly 3112, or the substrate to a target temperature. The temperature controller may include a heater, a heat transfer fluid, a channel 31110a, or a combination of these. The channel 31110a carries a heat transfer fluid such as brine or a gas. In one embodiment, the channel 31110a is defined inside the base 31110, and one or more heaters are located inside the ceramic member 31111a in the ESC 31111. The substrate support 311 may include a heat transfer gas supply to supply a heat transfer gas into a space between the back surface of the substrate W and the central portion 3111a.

The showerhead 313 introduces at least one processing gas from the gas supply 320 into the plasma processing space 310s. The showerhead 313 includes at least one gas inlet 313a, at least one gas-diffusion compartment 313b, and multiple gas guides 313c. The processing gas supplied to the gas inlet 313a passes through the gas-diffusion compartment 313b and is introduced into the plasma processing space 310s through the multiple gas guides 313c. The showerhead 313 further includes at least one upper electrode. In addition to the showerhead 313, the gas guide unit may include one or more side gas injectors (SGIs) installed in one or more openings in the sidewall 310a.

The gas supply 320 may include at least one gas source 321 and at least one flow controller 322. In one embodiment, the gas supply 320 supplies at least one processing gas from each gas source 321 to the showerhead 313 through the corresponding flow controller 322. The flow controller 322 may be, for example, a mass flow controller or a pressure-based flow controller. The gas supply 320 may further include one or more flow rate modulators that cause at least one processing gas to be supplied at a modulated flow rate or in a pulsed manner.

The power supply 330 includes the RF power supply 331 coupled to the plasma processing chamber 310 through at least one impedance matching circuit. The RF power supply 331 provides at least one RF signal (RF power) to at least one lower electrode or at least one upper electrode, or both. This generates a plasma from at least one processing gas supplied into the plasma processing space 310s. The RF power supply 331 may thus function as at least a part of a plasma generator that generates a plasma from one or more processing gases in the plasma processing chamber 310. A bias RF signal is provided to at least one lower electrode to generate a bias potential in the substrate W, thus drawing ion components in the generated plasma toward the substrate W.

In one embodiment, the RF power supply 331 includes a first RF generator 331a and a second RF generator 331b. The first RF generator 331a is coupled to at least one lower electrode or at least one upper electrode, or both through at least one impedance matching circuit to generate a source RF signal (source RF power) for plasma generation. In one embodiment, the source RF signal has a frequency in a range of 10 to 150 MHz. In one embodiment, the first RF generator 331a may generate multiple source RF signals with different frequencies. The one or more generated source RF signals are provided to at least one lower electrode or at least one upper electrode, or both.

The second RF generator 331b is coupled to at least one lower electrode through at least one impedance matching circuit to generate a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 331b may generate multiple bias RF signals with different frequencies. The one or more generated bias RF signals are provided to at least one lower electrode. In various embodiments, at least one of the source RF signal or the bias RF signal may be pulsed.

The power supply 330 may include the DC power supply 332 coupled to the plasma processing chamber 310. The DC power supply 332 includes a first DC generator 332a and a second DC generator 332b. In one embodiment, the first DC generator 332a is coupled to at least one lower electrode to generate a first DC signal. The generated first bias DC signal is applied to at least one lower electrode. In one embodiment, the second DC generator 332b is coupled to at least one upper electrode to generate a second DC signal. The generated second DC signal is applied to at least one upper electrode.

In various embodiments, at least one of the first DC signal or the second DC signal may be pulsed. In this case, the sequence of voltage pulses is applied to at least one lower electrode or at least one upper electrode, or both. The voltage pulses may have rectangular, trapezoidal, or triangular pulse waveforms, or a combination of these. In one embodiment, a waveform generator for generating a sequence of voltage pulses based on DC signals is coupled between the first DC generator 332a and at least one lower electrode. Thus, the first DC generator 332a and the waveform generator form a voltage pulse generator. When the second DC generator 332b and the waveform generator form a voltage pulse generator, the voltage pulse generator is coupled to at least one upper electrode. The voltage pulses may have positive polarity or negative polarity. The sequence of voltage pulses may include one or more positive voltage pulses and one or more negative voltage pulses within one cycle. The power supply 330 may include the first DC generator 332a and the second DC generator 332b in addition to the RF power supply 331 or may include the first DC generator 332a in place of the second RF generator 331b.

The exhaust system 340 is connectable to, for example, a gas outlet 310e in the bottom of the plasma processing chamber 310. The exhaust system 340 may include a pressure control valve and a vacuum pump. The pressure control valve regulates the pressure in the plasma processing space 310s. The vacuum pump may be a turbomolecular pump, a dry pump, or a combination of these.

The plasma processing apparatus 3 includes a controller 5. The controller 5 processes computer-executable instructions that cause the plasma processing apparatus 3 to perform various types of processing described in one or more embodiments of the present disclosure. The controller 5 may cause the components of the plasma processing apparatus 3 to perform the various types of processing described herein. In one embodiment, some or all of the components of the controller 5 may be included in the plasma processing apparatus 3. The controller 5 may include a processor 5a1, a storage 5a2, a communicator 5a3, and a user interface 5a4. The controller 5 is implemented by, for example, a computer 5a. In response to a user operation through the user interface 5a4, the processor 5a1 may perform various control operations by loading a program from the storage 5a2 and executing a program 5a25 loaded. In the present embodiment, the program is prestored in the storage 5a2. In some embodiments, the program may be obtained through a medium as appropriate. The obtained program is stored into the storage 5a2 to be loaded from the storage 5a2 and executed by the processor 5a1. The medium may be one of various storage media readable by the computer 5a or may be the network 4 connected to the communicator 5a3. The processor 5a1 may be a central processing unit (CPU). The storage 5a2 may include a random-access memory (RAM), a read-only memory (ROM), a hard disk drive (HDD), a solid-state drive (SSD), or a combination of these. The communicator 5a3 may communicate with the plasma processing apparatus 3 through the network 4 such as a local area network (LAN). The user interface 5a4 may include an input device such as a keyboard and an output device such as a display.

### Structure of Computer 5a

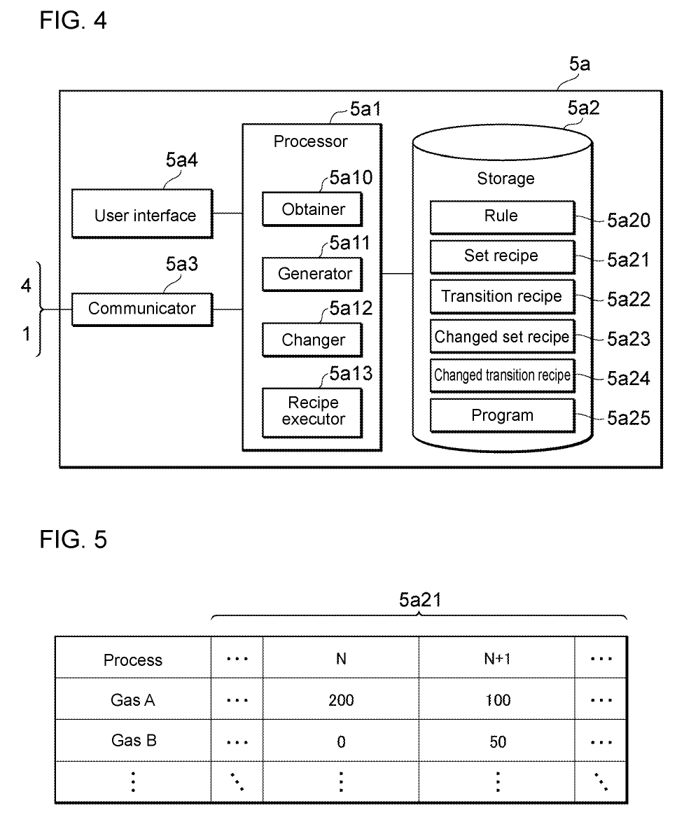

FIG. 4 is a diagram of an example of the computer 5a included in the controller 5. The computer 5a in the present embodiment includes the processor 5a1, the storage 5a2, the communicator 5a3, and the user interface 5a4.

The storage 5a2 stores rules 5a20, set recipes 5a21, transition recipes 5a22, changed set recipes 5a23, changed transition recipes 5a24, and the program 5a25. The processor 5a1 executes the program 5a25 loaded from the storage 5a2 to implement an obtainer 5a10, a generator 5a11, a changer 5a12, and a recipe executor 5a13.

The obtainer 5a10 obtains the rules including the first rule and the second rule from the creation apparatus 2 through the communicator 5a3 and the network 4, and stores the obtained rules into the storage 5a2 as the rules 5a20. The obtainer 5a10 also obtains the set recipes from the creation apparatus 2 through the communicator 5a3 and the network 4, and stores the obtained set recipes into the storage 5a2 as the set recipes 5a21. The obtainer 5a10 is an example of a first recipe obtainer, a second recipe obtainer, and a rule obtainer.

FIG. 5 is a table showing an example of a set recipe 5a21. In process N, the flow rate of gas A is 200 sccm (3.3 × 10⁻⁶ m³/s) and the flow rate of gas B is 0 in the example in FIG. 5. In process N + 1 performed subsequently to process N, the flow rate of gas A is 100 sccm and the flow rate of gas B is 50 sccm in the example in FIG. 5. Gas A and gas B are examples of a processing gas.

Process N is an example of first plasma processing. Process N + 1 is an example of second plasma processing. In FIG. 5, the flow rates of gas A and gas B associated with process N are examples of a first recipe, and the flow rates of gas A and gas B associated with process N + 1 are examples of a second recipe. Each of the flow rates of gas A and gas B shown in FIG. 5 is an example of a set parameter. Examples of the set parameter also include a magnitude of RF power (power level) and a pressure in the plasma processing chamber 310.

Referring back to FIG. 4, the generator 5a11 generates a transition recipe based on the first rule of the rules 5a20 stored in the storage 5a2, and stores the generated transition recipe into the storage 5a2 as the transition recipe 5a22. The generator 5a11 is an example of a transition recipe generator.

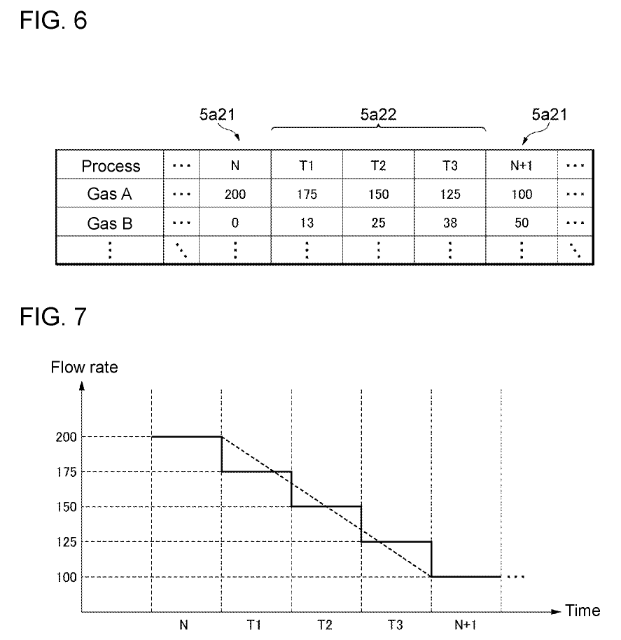

FIG. 6 is a table showing examples of the set recipes 5a21 and the transition recipe 5a22. The transition recipe 5a22 is for a process performed between two processes to reduce a change in the state of the plasma processing apparatus 3 resulting from switching between the two processes. In the example in FIG. 6, three transition processes T1, T2, and T3 are inserted between process N and process N + 1.

The flow rate of gas A in each transition process is set to allow the flow rate of gas A to gradually decrease from 200 to 100 sccm in the three transition processes T1, T2, and T3, as shown in FIG. 7. The flow rate of gas B in each transition process is set to allow the flow rate of gas B to gradually increase from 0 to 50 sccm in the three transition processes T1, T2, and T3.

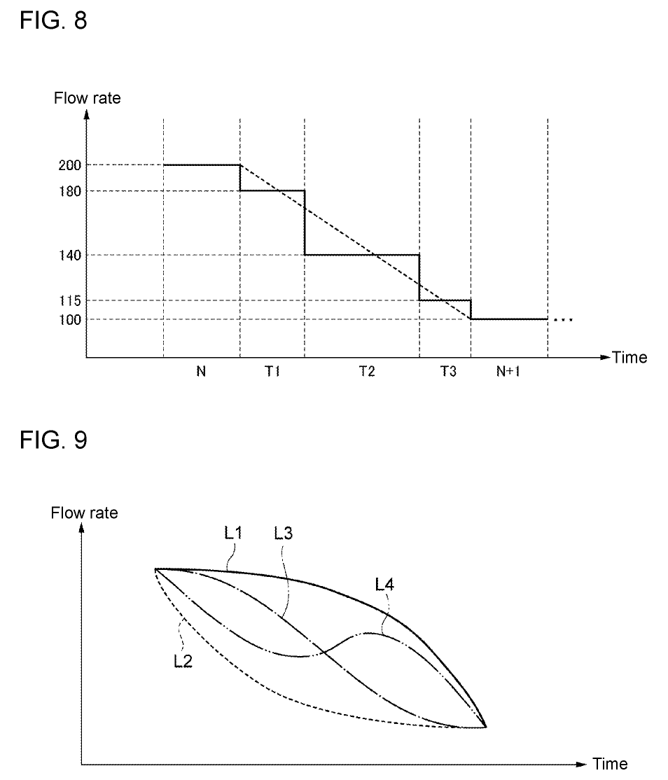

Although the three transition processes T1, T2, and T3 are inserted between process N and process N + 1 in the example in FIG. 6, the technique according to one or more embodiments of the present disclosure is not limited to this example. In another example, fewer or greater than three transition processes may be inserted between process N and process N + 1. The duration of each process inserted between process N and process N + 1 may be set separately as shown in, for example, FIG. 8. In the example in FIG. 8, the duration of transition process T2 is the longest and the duration of transition process T3 is the shortest of the three transition processes T1, T2, and T3. The user can set the number of transition processes and the duration of each transition process through the creation apparatus 2.

Although the flow rates of a gas in the transition processes shown in FIGS. 7 and 8 are set to gradually change along a straight line, the technique according to one or more embodiments of the present disclosure is not limited to these examples. In another example, the flow rate of the gas in the transition processes may be set to gradually change along a curve L1 that bends upward or a curve L2 that bends downward as shown in, for example, FIG. 9.

The flow rate of the gas in the transition processes may be set to gradually change along a curve L3 that bends more gradually toward the preceding process (process N) and the succeeding process (process N + 1) as shown in, for example, FIG. 9.

As shown in, for example, FIG. 9, the flow rate of the gas in the transition processes may be set to gradually change along a curve L4 that includes a period in which the flow rate shifts to an increase during the transition processes instead of decreasing monotonically. When the flow rate of the gas is to be increased, the flow rate may be set to gradually change along a curve that includes a period in which the flow rate shifts to a decrease during the transition processes instead of increasing monotonically.

Referring back to FIG. 4, the changer 5a12 changes the values of the set parameters included in the set recipes 5a21 based on the operation time of the RF power supply 331 and the second rule of the rules 5a20 stored in the storage 5a2. For example, the changer 5a12 changes the flow rates of gas A and gas B in process N and process N + 1 based on the operation time of the RF power supply 331 and the second rule. The changer 5a12 stores the recipe including the changed flow rates of gas A and gas B into the storage 5a2 as a changed set recipe 5a23.

The changer 5a12 also changes the transition recipe 5a22 based on the first rule of the rules 5a20 and the changed set recipe 5a23 stored in the storage 5a2. For example, the changer 5a12 changes the transition recipe 5a22 to allow the flow rates of gas A and gas B in process N to gradually change to those in process N + 1 based on the first rule. The changer 5a12 then stores the transition recipe 5a22 after the change into the storage 5a2 as the changed transition recipe 5a24. The changer 5a12 is an example of a first recipe changer, a second recipe changer, and a transition recipe changer.

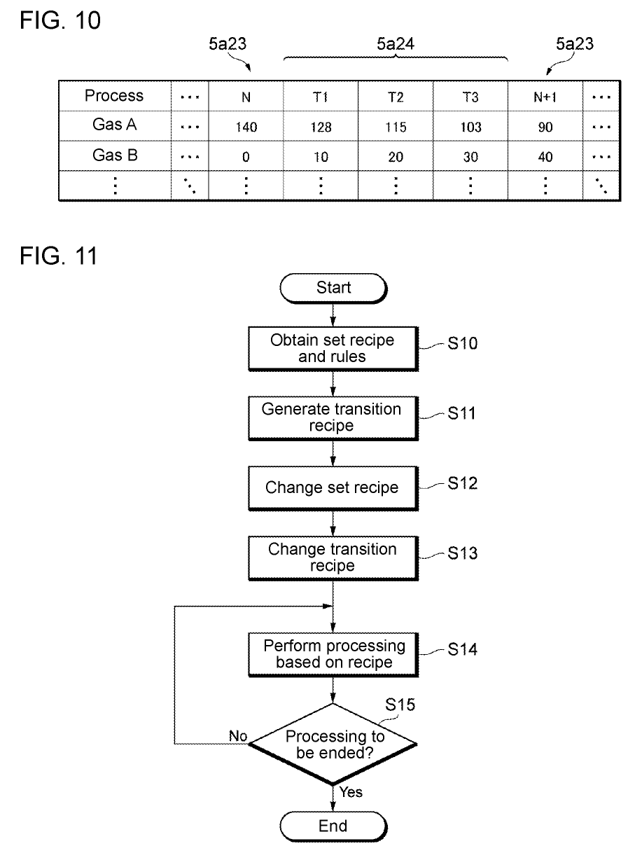

This generates the changed set recipe 5a23 and the changed transition recipe 5a24 shown in, for example, FIG. 10. FIG. 10 shows the changed set recipe 5a23 and the changed transition recipe 5a24 after a predetermined operation time of the RF power supply 331.

In the example in FIG. 10, the flow rate of gas A in the changed set recipe 5a23 for process N is decreased from 200 to 140 sccm, and the flow rate of gas A in the changed set recipe 5a23 for process N + 1 is decreased from 100 to 90 sccm. The flow rate of gas B in the changed set recipe 5a23 for process N + 1 is also decreased from 50 to 40 sccm.

In the example in FIG. 10, the flow rates of each gas in the changed transition recipe 5a24 for transition processes T1 to T3 are changed to allow the flow rate of the gas in the changed set recipe 5a23 for process N to gradually change to the flow rate of the gas in the changed set recipe 5a23 for process N + 1.

When the flow rates of each gas in the transition processes between process N and process N + 1 are fixed, changing the flow rates of the gas in process N and process N + 1 based on the operation time of the RF power supply 331 causes the flow rate of the gas to fluctuate wastefully. For example, when the transition recipe 5a22 shown in FIG. 6 is set in place of the changed transition recipe 5a24 in FIG. 10, the flow rate of gas A is to temporarily increase from 140 to 175 sccm before decreasing. The flow rate of gas A is to greatly decrease from 125 to 90 sccm between transition process T3 and process N + 1. This can cause a large change in the state of the plasma processing apparatus 3, further causing a failure such as extinguishment of the plasma.

In the present embodiment, the flow rates of each gas in the changed transition recipe 5a24 for the three transition processes T1, T2, and T3 are changed to allow the flow rate of the gas in process N to gradually change to the flow rate of the gas in process N + 1 as shown in, for example, FIG. 10. This reduces a change in the state of the plasma processing apparatus 3 to smoothly switch processing between two processes N and N + 1 each with a different processing condition.

Referring back to FIG. 4, the recipe executor 5a13 controls the components of the plasma processing apparatus 3 based on the set recipe 5a21 and the transition recipe 5a22 stored in the storage 5a2, causing plasma processing to be performed on the substrate W. The recipe executor 5a13 obtains the changed set recipe 5a23 and the changed transition recipe 5a24 from the storage 5a2 based on the operation time of the RF power supply 331. The recipe executor 5a13 then controls the components of the plasma processing apparatus 3 based on the changed set recipe 5a23 and the changed transition recipe 5a24 that have been obtained, causing plasma processing to be performed on the substrate W.

### Plasma Processing Method

FIG. 11 is a flowchart of an example plasma processing method. The steps shown in FIG. 11 are performed by the components of the plasma processing apparatus 3 controlled by the controller 5 in the plasma processing apparatus 3.

A set recipe and rules are obtained first (step S10). In step S10, the obtainer 5a10 obtains, through the communicator 5a3 and the network 4, rules including the first rule and the second rule from the creation apparatus 2 and stores the obtained rules into the storage 5a2 as the rules 5a20. In step S10, the obtainer 5a10 also obtains, through the communicator 5a3 and the network 4, a set recipe from the creation apparatus 2 and stores the obtained set recipe into the storage 5a2 as the set recipe 5a21. Step S10 is an example of obtaining a first recipe, obtaining a second recipe, and obtaining a rule.

A transition recipe is then generated (step S11). In step S11, the generator 5a11 generates a transition recipe based on the first rule of the rules 5a20 stored in the storage 5a2, and stores the generated transition recipe into the storage 5a2 as the transition recipe 5a22. Step S11 is an example of generating a transition recipe.

The set recipe is then changed (step S12). In step S12, the changer 5a12 changes the values of the set parameters included in the set recipe 5a21 for each operation time of the RF power supply 331 based on the second rule of the rules 5a20 stored in the storage 5a2. The changer 5a12 then stores the set recipe 5a21 including the changed set parameters into the storage 5a2 as the changed set recipe 5a23. Step S12 is an example of changing a first recipe and changing a second recipe.

The transition recipe is then changed (step S13). In step S13, the changer 5a12 changes the transition recipe 5a22 based on the first rule of the rules 5a20 and the changed set recipe 5a23 stored in the storage 5a2. The changer 5a12 then stores the transition recipe 5a22 including the changed set parameters into the storage 5a2 as the changed set recipe 5a23. Step S13 is an example of changing a transition recipe.

The substrate W is then processed based on the recipe (step S14). In step S14, the recipe executor 5a13 controls the components of the plasma processing apparatus 3 based on the set recipe 5a21 and the transition recipe 5a22 stored in the storage 5a2, causing plasma processing to be performed on the substrate W. The recipe executor 5a13 also obtains the changed set recipe 5a23 and the changed transition recipe 5a24 corresponding to the operation time of the RF power supply 331 from the storage 5a2. The recipe executor 5a13 then controls the components of the plasma processing apparatus 3 based on the changed set recipe 5a23 and the changed transition recipe 5a24 that have been obtained, causing plasma processing to be performed on the substrate W.

The determination is then performed as to whether the processing on the substrate W is to be ended (step S15). When the processing on the substrate W is not to be ended (No in step S15), the processing in step S14 is performed again. When the processing on the substrate W is to be ended (Yes in step S15), the plasma processing method shown in the flowchart ends.

An embodiment has been described above. As described above, a plasma processing apparatus (plasma processing apparatus 3) according to the present embodiment includes a chamber (plasma processing chamber 310), a gas supply (gas supply 320), an RF power supply (RF power supply 331), and a controller (controller 5). The gas supply supplies a processing gas into the chamber. The RF power supply generates RF power to generate a plasma from the processing gas supplied into the chamber. The controller controls the gas supply and the RF power supply. The controller includes a processor (processor 5a1) and a storage (storage 5a2). The storage stores a first rule and a second rule. The first rule is used to generate a transition recipe for transition processes performed between first plasma processing and second plasma processing. The second rule is used to change the values of the set parameters for the first plasma processing and the values of the set parameters for the second plasma processing based on an operation time of the RF power supply. The processor includes a first recipe obtainer (obtainer 5a10), a second recipe obtainer (obtainer 5a10), a rule obtainer (obtainer 5a10), a transition recipe generator (generator 5a11), a first recipe changer (changer 5a12), a second recipe changer (changer 5a12), and a transition recipe changer (changer 5a12). The first recipe obtainer obtains a first recipe including the values of the set parameters for the first plasma processing. The second recipe obtainer obtains a second recipe including the values of the set parameters for the second plasma processing. The rule obtainer obtains the first rule from an external device and causes the storage to store the obtained first rule. The transition recipe generator generates a transition recipe based on the first rule. The first recipe changer changes the values of the set parameters included in the first recipe based on the operation time of the RF power supply and the second rule. The second recipe changer changes the values of the set parameters included in the second recipe based on the operation time of the RF power supply and the second rule. The transition recipe changer changes the transition recipe based on the first rule, the first recipe changed by the first recipe changer, and the second recipe changed by the second recipe changer. This allows the rules used in the plasma processing apparatus to be corrected easily and externally.

In the above embodiment, the set parameter is at least one of the magnitude of the RF power, the flow rate of the processing gas, or the pressure in the chamber.

A program (5a25) according to the above embodiment controls a plasma processing apparatus. The plasma processing apparatus (plasma processing apparatus 3) includes a chamber (plasma processing chamber 310), a gas supply (gas supply 320), an RF power supply (RF power supply 331), and a controller (controller 5). The gas supply supplies a processing gas into the chamber. The RF power supply generates RF power to generate a plasma from the processing gas supplied into the chamber. The controller controls the gas supply and the RF power supply. The controller includes a processor (processor 5a1) and a storage (storage 5a2). The storage stores a first rule and a second rule. The first rule is used to generate a transition recipe for transition processes performed between first plasma processing and second plasma processing. The second rule is used to change the values of the set parameters for the first plasma processing and the values of the set parameters for the second plasma processing based on an operation time of the RF power supply. The program causes the processor to perform obtaining a first recipe (step S10), obtaining a second recipe (step S10), obtaining a rule (step S10), generating a transition recipe (step S11), changing a first recipe (step S12), changing a second recipe (step S12), and changing a transition recipe (step S13). In obtaining the first recipe, a first recipe including the values of the set parameters for the first plasma processing is obtained. In obtaining the second recipe, a second recipe including the values of the set parameters for the second plasma processing is obtained. In obtaining the rule, the first rule is obtained from an external device and stored into the storage. In generating the transition recipe, a transition recipe is generated based on the first rule. In changing the first recipe, the values of the set parameters included in the first recipe are changed based on the operation time of the RF power supply and the second rule. In changing the second recipe, the values of the set parameters included in the second recipe are changed based on the operation time of the RF power supply and the second rule. In changing the transition recipe, the transition recipe is changed based on the first rule, the first recipe changed in changing the first recipe, and the second recipe changed in changing the second recipe. This allows the rules used in the plasma processing apparatus to be corrected easily and externally.

A plasma processing system 1 according to the above embodiment includes a rule creation apparatus (creation apparatus 2) and a plasma processing apparatus (plasma processing apparatus 3). The rule creation apparatus includes a rule creator (creator 210) and a transmitter (transmitter 211). The rule creator creates a first rule used to generate a transition recipe for the transition processes performed between the first plasma processing and the second plasma processing. The transmitter transmits the first rule to the plasma processing apparatus. The plasma processing apparatus includes a chamber (plasma processing chamber 310), a gas supply (gas supply 320), an RF power supply (RF power supply 331), and a controller (controller 5). The gas supply supplies a processing gas into the chamber. The RF power supply generates RF power to generate a plasma from the processing gas supplied into the chamber. The controller controls the gas supply and the RF power supply. The controller includes a processor (processor 5a1) and a storage (storage 5a2). The storage stores a first rule and a second rule. The first rule is used to generate a transition recipe for transition processes performed between first plasma processing and second plasma processing. The second rule is used to change the values of the set parameters for the first plasma processing and the values of the set parameters for the second plasma processing based on an operation time of the RF power supply. The processor includes a first recipe obtainer (obtainer 5a10), a second recipe obtainer (obtainer 5a10), a rule obtainer (obtainer 5a10), a transition recipe generator (generator 5a11), a first recipe changer (changer 5a12), a second recipe changer (changer 5a12), and a transition recipe changer (changer 5a12). The first recipe obtainer obtains a first recipe including the values of the set parameters for the first plasma processing. The second recipe obtainer obtains a second recipe including the values of the set parameters for the second plasma processing. The rule obtainer obtains the first rule from the rule creation apparatus and causes the storage to store the obtained first rule. The transition recipe generator generates a transition recipe based on the first rule. The first recipe changer changes the values of the set parameters included in the first recipe based on the operation time of the RF power supply and the second rule. The second recipe changer changes the values of the set parameters included in the second recipe based on the operation time of the RF power supply and the second rule. The transition recipe changer changes the transition recipe based on the first rule, the first recipe changed by the first recipe changer, and the second recipe changed by the second recipe changer. This allows the rules used in the plasma processing apparatus to be corrected easily and externally.

### Modifications

The technique according to one or more embodiments described in the present application is not limited to the embodiment described above, and may be changed variously within the scope of the present disclosure.

In the above embodiment, the changer 5a12 changes, in step S12, the values of the set parameters in the set recipes 5a21 for each operation time of the RF power supply 331 based on the second rule, and stores the set recipes 5a21 as the changed set recipes 5a23. This changes the set levels of the set parameters (e.g., a set power level of the RF power or a set flow rate of the processing gas) over time based on the operation time of the RF power supply 331. However, the set levels of the set parameters may be changed over time in any other manner.

For example, the obtainer 5a10 may obtain, in step S12, the changed set recipe 5a23 from the creation apparatus 2 through the communicator 5a3 and the network 4 for each operation time of the RF power supply. The changer 512a may then store the changed set recipe 5a23 obtained by the obtainer 5a10 into the storage 5a2. This may change the set levels of the set parameters over time based on the operation time of the RF power supply 331.

For example, the obtainer 5a10 may obtain, in step S12, the set levels of the set parameters from the user through the user interface 5a4 for each operation time of the RF power supply. The changer 512a may then update the set recipe 5a21 based on the obtained set levels of the set parameters and store the set recipe 5a21 into the storage 5a2 as the changed set recipe 5a23. This may change the set levels of the set parameters over time based on the operation time of the RF power supply 331.

In the above embodiment, the set recipe 5a21 (FIG. 5) and the transition recipe 5a22 (FIG. 6), as well as the changed set recipe 5a23 and the changed transition recipe 5a24 (FIG. 10) are described using gas A and gas B as the set parameters. However, the set parameters are not limited to gas A and gas B, and the recipes can include other parameters.

For example, the set parameters may include various control parameters included in a recipe, such as a power level of the RF power (source RF signal) and a pressure in the plasma processing chamber 310. In one example, the set parameters include a power level of bias RF power (a bias RF signal). In one example, the set parameters include a voltage level of a DC voltage (first bias DC signal) applied to the lower electrode. In one example, the set parameters include a voltage level of the DC voltage applied to the ring assembly 3112. In one example, the set parameters include a voltage level of a DC voltage (second DC signal) applied to the upper electrode. In one example, the set parameters include a partial pressure ratio of the processing gas in each portion (e.g., a central portion and an outer peripheral portion surrounding the central portion) of the plasma processing chamber.

In one embodiment, the plasma processing apparatus 3 includes an electromagnet assembly that generates a magnetic field in the chamber 310. The electromagnet assembly includes, for example, multiple electromagnets or bobbins (yokes) located above the showerhead 313. In one embodiment, the electromagnet assembly includes multiple annular electromagnets arranged concentrically above the plasma processing space 310s. The current value applied to the electromagnet assembly may be controlled to adjust the radial distribution of density of the plasma generated in the chamber 310. The set parameters may include a magnitude of the current value applied to the electromagnet assembly.

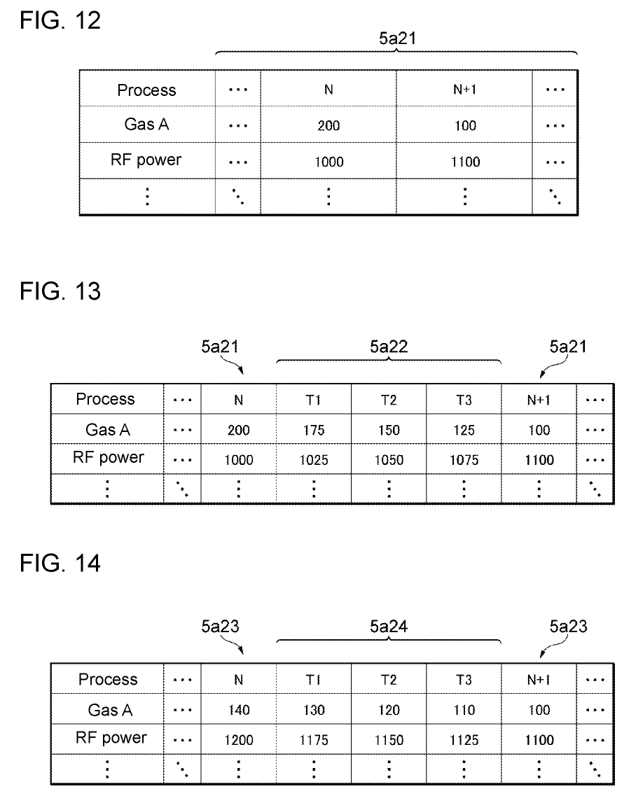

FIG. 12 is a table showing another example set recipe. In process N, the flow rate of gas A is 200 sccm (3.3 × 10⁻⁶ m³/s), and the power level of the RF power (source RF signal) is 1000 W in the example in FIG. 12. The flow rate of gas A and the RF power level associated with process N are examples of a first recipe. In the example in FIG. 12, the flow rate of gas A is 100 sccm and the power level of the RF power is 1100 W in process N + 1 performed subsequently to process N. The flow rate of gas A and the RF power level associated with process N + 1 are examples of a second recipe.

FIG. 13 is a table showing other example set recipes and another example transition recipe. The transition recipe 5a22 is for a process performed between two processes to reduce a change in the state of the plasma processing apparatus 3 resulting from switching between the two processes. In the example in FIG. 13, three transition processes T1, T2, and T3 are inserted between process N and process N + 1. Fewer or greater than three transition processes may be inserted between process N and process N + 1. The duration of some or all the transition processes inserted between process N and process N + 1 may be the same or different.

The flow rate of gas A and the power level of the RF power in the transition processes are set based on the first rule of the rules 5a20 stored in the storage 5a2. In one embodiment, the first rule includes a first change rule and a second change rule.

The first change rule sets the flow rate of gas A in the transition processes. In one example, the first change rule is set to allow the flow rate of gas A to gradually change from the flow rate of gas A associated with process N to the flow rate of gas A associated with process N + 1. The first change rule may be set to allow the flow rate of gas A in the multiple transition processes to gradually change along a straight line (refer to FIGS. 7 and 8) or a curve (refer to FIG. 9).

The second change rule sets the power level of the RF power in the transition processes. In one example, the second change rule is set to allow the power level of the RF power to gradually change from the power level of the RF power associated with process N to the power level of the RF power associated with process N + 1. The second change rule may be set to allow the power level of the RF power in the multiple transition processes to gradually change along a straight line or a curve.

The transition recipe 5a22 may be generated by the generator 5a11 based on the first change rule and the second change rule for the first rule of the rules 5a20 stored in the storage 5a2. In the example in FIG. 13, the flow rate of gas A in each transition process is set to allow the flow rate of gas A to gradually decrease from 200 to 100 sccm in the three transition processes T1, T2, and T3 based on the first change rule. The power level of the RF power in each transition process is set to allow the power level of the RF power to gradually increase from 1000 to 1100 W in the three transition processes T1, T2, and T3 based on the second change rule.

FIG. 14 is a table showing other example changed set recipes and another example changed transition recipe. In the example in FIG. 14, the flow rate of gas A in the changed set recipe 5a23 for process N is decreased from 200 to 140 sccm. The flow rate of gas A in the changed set recipe 5a23 for process N + 1 is 100 sccm, which is the same as the flow rate of gas A in the set recipe 5a21. The power level of the RF power in the changed set recipe 5a23 for process N + 1 is increased from 1000 W to 1200 W. The power level of the RF power in the changed set recipe 5a23 for process N + 1 is 1100 W, which is the same as the power level of the RF power in the set recipe 5a21.

The changed transition recipe 5a24 may be generated by the changer 5a12 based on the first change rule and the second change rule for the first rule of the rules 5a20 stored in the storage 5a2. In the example in FIG. 14, the flow rate of gas A in each transition process is set to allow the flow rate of gas A to gradually decrease from 140 to 100 sccm in the three transition processes T1, T2, and T3 based on the first change rule. The power level of the RF power in each transition process is set to allow the power level of the RF power to gradually decrease from 1200 to 1100 W in the three transition processes T1, T2, and T3 based on the second change rule.

When the flow rates of each gas and the power levels of the RF power in the transition processes between process N and process N + 1 are fixed, changing the flow rates of the gas in process N and process N + 1 based on the operation time of the RF power supply 331 may cause a failure.

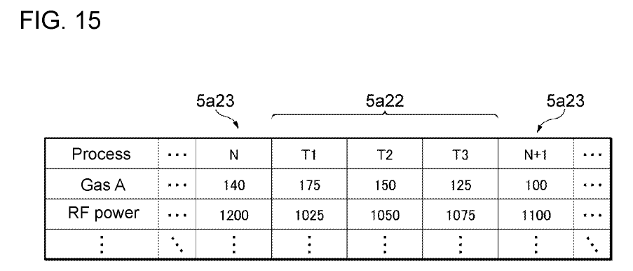

FIG. 15 is a table showing a recipe in a reference example. FIG. 15 shows an example in which the changed set recipes 5a23 (refer to FIG. 14) and the transition recipe 5a22 (refer to FIG. 13) are set in a fixed manner. In the example shown in FIG. 15, the flow rate of gas A increases from 140 sccm in process N to 175 sccm in transition process T1 and then continues to decrease in transition processes T2 and T3 to 100 sccm in process N + 1. The power level of the RF power decreases from 1200 W in process N to 1025 W in transition process T1 and then continues to increase in transition processes T2 and T3 to 1100 W in process N + 1. This can cause a large change in the state of the plasma processing apparatus 3, further causing a failure such as extinguishment of the plasma.

In the example shown in FIG. 14, the flow rates of the gas and the power levels of the RF power in the changed set recipe 5a23 for the three transition processes T1, T2, and T3 are changed to allow the flow rate of gas A and the power level of the RF power in process N to gradually change to those in process N + 1. This reduces a change in the state of the plasma processing apparatus 3 to smoothly switch processing between two processes N and N + 1 each with a different processing condition.

The plasma processing system 1 according to the above embodiment uses electric signals to transmit the rules and the set recipes from the creation apparatus 2 to the plasma processing apparatus 3 through the network 4. However, the technique according to one or more embodiments of the present disclosure is not limited to this example. In another example, the rules and the set recipes created by the creation apparatus 2 may be stored in a portable storage medium such as a universal serial bus (USB) memory or a digital versatile disc (DVD). The portable storage medium may be set in the controller 5 in the plasma processing apparatus 3 to allow the controller 5 to obtain the rules and the set recipes from the portable storage medium.

In the above embodiment, the changer 5a12 generates the changed set recipe 5a23 and the changed transition recipe 5a24 for each operation time of the RF power supply 331 before the start of the processing on the substrate W. However, the technique according to the present disclosure is not limited to this example. In another example, the changer 5a12 may generate the changed set recipe 5a23 and the changed transition recipe 5a24 every time the operation time of the RF power supply 331 reaches a predetermined time after the start of the processing on the substrate W.

Although the plasma processing apparatus 3 according to the above embodiment uses a capacitively coupled plasma (CCP) for processing as an example plasma source, the plasma source is not limited to a CCP. Plasma sources other than a CCP include, for example, an inductively coupled plasma (ICP), a microwave-excited surface wave plasma (SWP), an electron cyclotron resonance plasma (ECP), and a helicon wave excited plasma (HWP).

In the above embodiment, the set levels of the set parameters are changed over time based on the operation time of the RF power supply 331. However, the technique according to the present disclosure is not limited to this example. For example, the set levels of the set parameters may be changed over time based on the state of a wearable component (e.g., the edge ring or the upper electrode) used in the plasma processing apparatus 3. The state of the wearable component may be determined based on the operation time of the plasma processing apparatus 3 and the measurement results of the wearable component, in addition to the operation time of the RF power supply 331 described above.

In the above embodiment, the plasma processing apparatus 3 is described as an example. However, the technique according to the present disclosure can be applied to other apparatuses. For example, the technique may be applicable to a substrate processing apparatus that does not use a plasma. In this case, a substrate processing system includes the substrate processing apparatus and a controller including a storage and a processor. The processor includes a first recipe obtainer, a second recipe obtainer, a transition recipe generator, a first recipe changer, a second recipe changer, and a transition recipe changer. The first recipe obtainer obtains a first recipe for first substrate processing. The first recipe includes first set levels of set parameters. In one embodiment, the first recipe includes multiple first set levels corresponding to the respective set parameters. The second recipe obtainer obtains a second recipe for second substrate processing. The second recipe includes second set levels of set parameters. In one embodiment, the second recipe includes multiple second set levels corresponding to the respective set parameters. The transition recipe generator generates a transition recipe for transition processes performed between the first substrate processing and the second substrate processing. The transition recipe includes, for each set parameter, multiple transition set levels that change from the first set level to the second set level based on the first rule. The first recipe changer changes the first recipe over time based on, for example, the operation time of the substrate processing apparatus. In one embodiment, the first recipe changer changes the first set levels of each set parameter over time. The second recipe changer changes the second recipe over time based on, for example, the operation time of the substrate processing apparatus. In one embodiment, the second recipe changer changes the second set levels of each set parameter over time. The transition recipe changer changes the transition recipe based on the changed first recipe and the changed second recipe. The changed transition recipe includes, for each set parameter, the changed transition set levels that change from the changed first set levels to the changed second set levels based on the first rule. The functionality of the controller may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry is hardware that carries out or is programmed to perform the recited functionality. The hardware may be any hardware disclosed herein which is programmed or configured to carry out the recited functionality.

The technique according to the above embodiment facilitates updates of recipes used in the plasma processing apparatus.

The embodiments of the present disclosure further include the aspects described below.

### Appendix 1

A plasma processing apparatus, comprising:

a chamber;

a gas supply configured to supply a processing gas into the chamber;

a radio-frequency power supply configured to generate radio-frequency power to generate a plasma from the processing gas supplied into the chamber; and

a controller configured to control the gas supply and the radio-frequency power supply, the controller including

a storage configured to store a first rule including a first change rule and a second change rule, and

a processor including

a first recipe obtainer configured to obtain a first recipe for first plasma processing, the first recipe including a first set power level of the radio-frequency power and a first set flow rate of the processing gas,

a second recipe obtainer configured to obtain a second recipe for second plasma processing, the second recipe including a second set power level of the radio-frequency power and a second set flow rate of the processing gas,

a transition recipe generator configured to generate a transition recipe for transition performed between the first plasma processing and the second plasma processing, the transition recipe including a plurality of transition flow rates changeable from the first set flow rate to the second set flow rate based on the first change rule and a plurality of transition power levels changeable from the first set power level to the second set power level based on the second change rule,

a first recipe changer configured to change the first recipe over time based on an operation time of the radio-frequency power supply and change the first set power level and the first set flow rate over time,

a second recipe changer configured to change the second recipe over time based on an operation time of the radio-frequency power supply and change the second set power level and the second set flow rate over time, and

a transition recipe changer configured to change the transition recipe based on the changed first recipe and the changed second recipe, the changed transition recipe including a plurality of changed transition flow rates changeable from the changed first set flow rate to the changed second set flow rate based on the first change rule and a plurality of changed transition power levels changeable from the changed first set power level to the changed second set power level based on the second change rule.

### Appendix 2

The plasma processing apparatus according to appendix 1, wherein

the controller further includes a rule obtainer configured to obtain the first rule from an external device through a network and cause the storage to store the first rule.

### Appendix 3

The plasma processing apparatus according to appendix 2, wherein

the first recipe obtainer obtains the first recipe from the external device through the network and causes the storage to store the first recipe, and

the second recipe obtainer obtains the second recipe from the external device through the network and causes the storage to store the second recipe.

### Appendix 4

The plasma processing apparatus according to any one of appendixes 1 to 3, wherein

the storage further stores a second rule,

the first recipe changer changes the first set power level and the first set flow rate over time based on the second rule, and

the second recipe changer changes the second set power level and the second set flow rate over time based on the second rule.

### Appendix 5

The plasma processing apparatus according to appendix 4, wherein

the controller further includes a rule obtainer configured to obtain the first rule and the second rule from an external device through a network and causes the storage to store the first rule and the second rule.

### Appendix 6

A program for controlling a plasma processing apparatus, the plasma processing apparatus including a chamber, a gas supply configured to supply a processing gas into the chamber, a radio-frequency power supply configured to generate radio-frequency power to generate a plasma from the processing gas supplied into the chamber, and a controller configured to control the gas supply and the radio-frequency power supply, the controller including a storage and a processor,

the program causing the processor in the controller to perform processes comprising:

(a) causing the storage to store a first rule including a first change rule and a second change rule;

(b) obtaining a first recipe for first plasma processing, the first recipe including a first set power level of the radio-frequency power and a first set flow rate of the processing gas;

(c) obtaining a second recipe for second plasma processing, the second recipe including a second set power level of the radio-frequency power and a second set flow rate of the processing gas;

(d) generating a transition recipe for transition performed between the first plasma processing and the second plasma processing, the transition recipe including a plurality of transition flow rates changeable from the first set flow rate to the second set flow rate based on the first change rule and a plurality of transition power levels changeable from the first set power level to the second set power level based on the second change rule;

(e) changing the first recipe over time based on an operation time of the radio-frequency power supply, the changing the first recipe including changing the first set power level and the first set flow rate over time;

(f) changing the second recipe over time based on an operation time of the radio-frequency power supply, the changing the second recipe including changing the second set power level and the second set flow rate over time; and

(g) changing the transition recipe based on the changed first recipe and the changed second recipe, the changed transition recipe including a plurality of changed transition flow rates changeable from the changed first set flow rate to the changed second set flow rate based on the first change rule, and a plurality of changed transition power levels changeable from the changed first set power level to the changed second set power level based on the second change rule.

### Appendix 7

The program according to appendix 6, wherein

(a) includes obtaining the first rule from an external device through a network and causing the storage to store the first rule.

### Appendix 8

The program according to appendix 7, wherein

(b) includes obtaining the first recipe from the external device through the network and causing the storage to store the first recipe, and

(c) includes obtaining the second recipe from the external device through the network and causing the storage to store the second recipe.

### Appendix 9

The program according to any one of appendixes 6 to 8, wherein

(a) includes causing the storage to store a second rule,

(e) includes changing the first set power level and the first set flow rate over time based on the second rule, and

(f) includes changing the second set power level and the second set flow rate over time based on the second rule.

### Appendix 10

The program according to appendix 9, wherein

(a) includes obtaining the first rule and the second rule from an external device through a network and causing the storage to store the first rule and the second rule.

### Appendix 11

A plasma processing apparatus, comprising:

a chamber;

a radio-frequency power supply configured to generate radio-frequency power to generate a plasma in the chamber; and

a controller including

a storage configured to store a first rule, and

a processor including

a first recipe obtainer configured to obtain a first recipe for first plasma processing, the first recipe including a first set level of a set parameter,

a second recipe obtainer configured to obtain a second recipe for second plasma processing, the second recipe including a second set level of the set parameter,

a transition recipe generator configured to generate a transition recipe for transition performed between the first plasma processing and the second plasma processing, the transition recipe including a plurality of transition set levels changeable from the first set level to the second set level based on the first rule,

a first recipe changer configured to change the first recipe over time based on an operation time of the radio-frequency power supply and change the first set level over time,

a second recipe changer configured to change the second recipe over time based on an operation time of the radio-frequency power supply and change the second set level over time, and

a transition recipe changer configured to change the transition recipe based on the changed first recipe and the changed second recipe, the changed transition recipe including a plurality of changed transition set levels changeable from the changed first set level to the changed second set level based on the first rule.

### Appendix 12

The plasma processing apparatus according to appendix 11, wherein

the controller further includes a rule obtainer configured to obtain the first rule from an external device through a network and cause the storage to store the first rule.

### Appendix 13

The plasma processing apparatus according to appendix 12, wherein

the first recipe obtainer obtains the first recipe from the external device through the network and causes the storage to store the first recipe.

### Appendix 14

The plasma processing apparatus according to any one of appendixes 11 to 13, wherein

the storage further stores a second rule,

the first recipe changer changes the first set level over time based on the second rule, and

the second recipe changer changes the second set level over time based on the second rule.

### Appendix 15

The plasma processing apparatus according to appendix 14, wherein

the controller further includes a rule obtainer configured to obtain the first rule and the second rule from an external device through a network and cause the storage to store the first rule and the second rule.

### Appendix 16

The plasma processing apparatus according to any one of appendixes 11 to 15, wherein

the set parameter is at least one of a power level of the radio-frequency power, a flow rate of a processing gas supplied into the chamber, or a pressure in the chamber.

### Appendix 17

A storage medium storing the program according to any one of appendixes 6 to 10.

### Appendix 18

A method implementable with a plasma processing apparatus, the plasma processing apparatus including a chamber, a gas supply configured to supply a processing gas into the chamber, a radio-frequency power supply configured to generate radio-frequency power to generate a plasma from the processing gas supplied into the chamber, and a controller configured to control the gas supply and the radio-frequency power supply, the controller including a storage and a processor,

the method comprising:

(a) causing the storage to store a first rule including a first change rule and a second change rule;

(b) obtaining a first recipe for first plasma processing, the first recipe including a first set power level of the radio-frequency power and a first set flow rate of the processing gas;

(c) obtaining a second recipe for second plasma processing, the second recipe including a second set power level of the radio-frequency power and a second set flow rate of the processing gas;

(d) generating a transition recipe for transition performed between the first plasma processing and the second plasma processing, the transition recipe including a plurality of transition flow rates changeable from the first set flow rate to the second set flow rate based on the first change rule and a plurality of transition power levels changeable from the first set power level to the second set power level based on the second change rule;

(e) changing the first recipe over time based on an operation time of the radio-frequency power supply, the changing the first recipe including changing the first set power level and the first set flow rate over time;

(f) changing the second recipe over time based on an operation time of the radio-frequency power supply, the changing the second recipe including changing the second set power level and the second set flow rate over time; and

(g) changing the transition recipe based on the changed first recipe and the changed second recipe, the changed transition recipe including a plurality of changed transition flow rates changeable from the changed first set flow rate to the changed second set flow rate based on the first change rule, and a plurality of changed transition power levels changeable from the changed first set power level to the changed second set power level based on the second change rule.

### Appendix 19

A plasma processing system, comprising:

the plasma processing apparatus according to any one of appendixes 1 to 5 and 11 to 16; and

a rule creation apparatus including a rule creator configured to create the first rule and a transmitter configured to transmit the first rule to the plasma processing apparatus.

### Appendix 20

A plasma processing apparatus, comprising:

a chamber;

a gas supply configured to supply a processing gas into the chamber;

a radio-frequency power supply configured to generate radio-frequency power to generate a plasma from the processing gas supplied into the chamber; and

a controller configured to control the gas supply and the radio-frequency power supply, the controller including a processor and a storage, the storage being configured to store

a first rule used to generate a transition recipe for transition performed between first plasma processing and second plasma processing, and

a second rule used to change a value of a set parameter for the first plasma processing and a value of a set parameter for the second plasma processing based on an operation time of the radio-frequency power supply,

the processor including

a first recipe obtainer configured to obtain a first recipe including the value of the set parameter for the first plasma processing,

a second recipe obtainer configured to obtain a second recipe including the value of the set parameter for the second plasma processing,

a rule obtainer configured to obtain the first rule from an external device and cause the storage to store the first rule,

a transition recipe generator configured to generate the transition recipe based on the first rule,

a first recipe changer configured to change the value of the set parameter included in the first recipe based on the second rule and an operation time of the radio-frequency power supply,

a second recipe changer configured to change the value of the set parameter included in the second recipe based on the second rule and an operation time of the radio-frequency power supply, and

a transition recipe changer configured to change the transition recipe based on the first rule, the first recipe changed by the first recipe changer, and the second recipe changed by the second recipe changer.

### Appendix 21

The plasma processing apparatus according to appendix 20, wherein

the set parameter is at least one of a magnitude of the radio-frequency power, a flow rate of the processing gas, or a pressure in the chamber.

### Appendix 22

A program for controlling a plasma processing apparatus, the plasma processing apparatus including a chamber, a gas supply configured to supply a processing gas into the chamber, a radio-frequency power supply configured to generate radio-frequency power to generate a plasma from the processing gas supplied into the chamber, and a controller configured to control the gas supply and the radio-frequency power supply, the controller including a processor and a storage, the storage being configured to store a first rule used to generate a transition recipe for transition performed between first plasma processing and second plasma processing, and a second rule used to change a value of a set parameter for the first plasma processing and a value of a set parameter for the second plasma processing based on an operation time of the radio-frequency power supply,

the program causing the processor to perform processes comprising:

obtaining a first recipe including the value of the set parameter for the first plasma processing;

obtaining a second recipe including the value of the set parameter for the second plasma processing;

obtaining the first rule from an external device and cause the storage to store the first rule;

generating the transition recipe based on the first rule;

changing the value of the set parameter included in the first recipe based on the second rule and an operation time of the radio-frequency power supply;

changing the value of the set parameter included in the second recipe based on the second rule and an operation time of the radio-frequency power supply; and

changing the transition recipe based on the first rule, the first recipe changed in the changing the first recipe, and the second recipe changed in the changing the second recipe.

### Appendix 23

A plasma processing system, comprising:

a rule creation apparatus; and

a plasma processing apparatus,

the rule creation apparatus including

a rule creator configured to create a first rule used to generate a transition recipe for transition performed between first plasma processing and second plasma processing, and

a transmitter configured to transmit the first rule to the plasma processing apparatus,

the plasma processing apparatus including

a chamber,

a gas supply configured to supply a processing gas into the chamber,

a radio-frequency power supply configured to generate radio-frequency power to generate a plasma from the processing gas supplied into the chamber, and

a controller configured to control the gas supply and the radio-frequency power supply, the controller including a processor and a storage, the storage being configured to store

the first rule, and

a second rule used to change a value of a set parameter for the first plasma processing and a value of a set parameter for the second plasma processing based on an operation time of the radio-frequency power supply,

the processor including

a first recipe obtainer configured to obtain a first recipe including the value of the set parameter for the first plasma processing,

a second recipe obtainer configured to obtain a second recipe including the value of the set parameter for the second plasma processing,

a rule obtainer configured to obtain the first rule from the rule creation apparatus and cause the storage to store the first rule,

a transition recipe generator configured to generate the transition recipe based on the first rule,

a first recipe changer configured to change the value of the set parameter included in the first recipe based on the second rule and an operation time of the radio-frequency power supply,

a second recipe changer configured to change the value of the set parameter included in the second recipe based on the second rule and an operation time of the radio-frequency power supply, and

a transition recipe changer configured to change the transition recipe based on the first rule, the first recipe changed by the first recipe changer, and the second recipe changed by the second recipe changer.

The above embodiments are mere examples described for illustrative purposes and are not intended to limit the scope of the present disclosure. The embodiments may be modified in various manners without departing from the spirit and scope of the present disclosure. For example, one or more components in one embodiment may be added to the structure according to another embodiment. One or more components in one embodiment may be replaced with the corresponding one or more components in another embodiment.

The technique according to one exemplary embodiment of the present disclosure facilitates updates of recipes used in the plasma processing apparatus.

What is claimed is:

1. A plasma processing apparatus, comprising:
a chamber;
a gas supply configured to supply a processing gas into the chamber;
a radio-frequency power supply configured to generate radio-frequency power to generate a plasma from the processing gas supplied into the chamber; and
a controller configured to control the gas supply and the radio-frequency power supply, the controller including:
a storage configured to store a first rule including a first change rule and a second change rule, and
a processor including:
a first recipe obtainer configured to obtain a first recipe for first plasma processing, the first recipe including a first set power level of the radio-frequency power and a first set flow rate of the processing gas,
a second recipe obtainer configured to obtain a second recipe for second plasma processing, the second recipe including a second set power level of the radio-frequency power and a second set flow rate of the processing gas,
a transition recipe generator configured to generate a transition recipe for transition performed between the first plasma processing and the second plasma processing, the transition recipe including a plurality of transition flow rates changeable from the first set flow rate to the second set flow rate based on the first change rule and a plurality of transition power levels changeable from the first set power level to the second set power level based on the second change rule,
a first recipe changer configured to change the first recipe over time based on an operation time of the radio-frequency power supply and change the first set power level and the first set flow rate over time,
a second recipe changer configured to change the second recipe over time based on an operation time of the radio-frequency power supply and change the second set power level and the second set flow rate over time, and
a transition recipe changer configured to change the transition recipe based on the changed first recipe and the changed second recipe, the changed transition recipe including a plurality of changed transition flow rates changeable from the changed first set flow rate to the changed second set flow rate based on the first change rule and a plurality of changed transition power levels changeable from the changed first set power level to the changed second set power level based on the second change rule.

2. The plasma processing apparatus according to claim 1, wherein
the controller further includes a rule obtainer configured to obtain the first rule from an external device through a network and cause the storage to store the first rule.

3. The plasma processing apparatus according to claim 2, wherein
the first recipe obtainer obtains the first recipe from the external device through the network and causes the storage to store the first recipe, and
the second recipe obtainer obtains the second recipe from the external device through the network and causes the storage to store the second recipe.

4. The plasma processing apparatus according to claim 1, wherein
the storage further stores a second rule,
the first recipe changer changes the first set power level and the first set flow rate over time based on the second rule, and
the second recipe changer changes the second set power level and the second set flow rate over time based on the second rule.

5. The plasma processing apparatus according to claim 4, wherein
the controller further includes a rule obtainer configured to obtain the first rule and the second rule from an external device through a network and causes the storage to store the first rule and the second rule.

6. A program for controlling a plasma processing apparatus, the plasma processing apparatus including a chamber, a gas supply configured to supply a processing gas into the chamber, a radio-frequency power supply configured to generate radio-frequency power to generate a plasma from the processing gas supplied into the chamber, and a controller configured to control the gas supply and the radio-frequency power supply, the controller including a storage and a processor,
the program causing the processor in the controller to perform processes comprising:
(a) causing the storage to store a first rule including a first change rule and a second change rule;
(b) obtaining a first recipe for first plasma processing, the first recipe including a first set power level of the radio-frequency power and a first set flow rate of the processing gas;
(c) obtaining a second recipe for second plasma processing, the second recipe including a second set power level of the radio-frequency power and a second set flow rate of the processing gas;
(d) generating a transition recipe for transition performed between the first plasma processing and the second plasma processing, the transition recipe including a plurality of transition flow rates changeable from the first set flow rate to the second set flow rate based on the first change rule and a plurality of transition power levels changeable from the first set power level to the second set power level based on the second change rule;
(e) changing the first recipe over time based on an operation time of the radio-frequency power supply, the changing the first recipe including changing the first set power level and the first set flow rate over time;
(f) changing the second recipe over time based on an operation time of the radio-frequency power supply, the changing the second recipe including changing the second set power level and the second set flow rate over time; and
(g) changing the transition recipe based on the changed first recipe and the changed second recipe, the changed transition recipe including a plurality of changed transition flow rates changeable from the changed first set flow rate to the changed second set flow rate based on the first change rule, and a plurality of changed transition power levels changeable from the changed first set power level to the changed second set power level based on the second change rule.

7. The program according to claim 6, wherein
(a) includes obtaining the first rule from an external device through a network and causing the storage to store the first rule.

8. The program according to claim 7, wherein
(b) includes obtaining the first recipe from the external device through the network and causing the storage to store the first recipe, and
(c) includes obtaining the second recipe from the external device through the network and causing the storage to store the second recipe.

9. The program according to claim 6, wherein
(a) includes causing the storage to store a second rule,
(e) includes changing the first set power level and the first set flow rate over time based on the second rule, and
(f) includes changing the second set power level and the second set flow rate over time based on the second rule.

10. The program according to claim 9, wherein
(a) includes obtaining the first rule and the second rule from an external device through a network and causing the storage to store the first rule and the second rule.

11. A plasma processing apparatus, comprising:
a chamber;
a radio-frequency power supply configured to generate radio-frequency power to generate a plasma in the chamber; and
a controller including
a storage configured to store a first rule, and
a processor including
a first recipe obtainer configured to obtain a first recipe for first plasma processing, the first recipe including a first set level of a set parameter,
a second recipe obtainer configured to obtain a second recipe for second plasma processing, the second recipe including a second set level of the set parameter,
a transition recipe generator configured to generate a transition recipe for transition performed between the first plasma processing and the second plasma processing, the transition recipe including a plurality of transition set levels changeable from the first set level to the second set level based on the first rule,
a first recipe changer configured to change the first recipe over time based on an operation time of the radio-frequency power supply and change the first set level over time,
a second recipe changer configured to change the second recipe over time based on an operation time of the radio-frequency power supply and change the second set level over time, and
a transition recipe changer configured to change the transition recipe based on the changed first recipe and the changed second recipe, the changed transition recipe including a plurality of changed transition set levels changeable from the changed first set level to the changed second set level based on the first rule.

12. The plasma processing apparatus according to claim 11, wherein
the controller further includes a rule obtainer configured to obtain the first rule from an external device through a network and cause the storage to store the first rule.

13. The plasma processing apparatus according to claim 12, wherein
the first recipe obtainer obtains the first recipe from the external device through the network and causes the storage to store the first recipe.

14. The plasma processing apparatus according to claim 11, wherein
the storage further stores a second rule,
the first recipe changer changes the first set level over time based on the second rule, and
the second recipe changer changes the second set level over time based on the second rule.

15. The plasma processing apparatus according to claim 14, wherein
the controller further includes a rule obtainer configured to obtain the first rule and the second rule from an external device through a network and cause the storage to store the first rule and the second rule.

16. The plasma processing apparatus according to claim 11, wherein
the set parameter is at least one of a power level of the radio-frequency power, a flow rate of a processing gas supplied into the chamber, or a pressure in the chamber.
